(19) United States
(12) Patent Application Publication
(10) Pub. No.: US 2026/0299227 A1
(43) Pub. Date: Oct. 1, 2026

(54) PROCESSOR PACKAGE INTEGRATED WITH OPTICAL ENGINE, ELECTRONIC DEVICE INCLUDING THE PROCESSOR PACKAGE, AND METHOD OF MANUFACTURING THE PROCESSOR PACKAGE

(71) Applicant: SAMSUNG ELECTRONICS CO., LTD., Suwon-si (KR)

(72) Inventors: Heejin CHOI, Suwon-si (KR); Woosung KIM, Suwon-si (KR)

(73) Assignee: SAMSUNG ELECTRONICS CO, LTD., Suwon-si (KR)

(21) Appl. No.: 19/566,336

(22) Filed: Mar. 13, 2026

(30) Foreign Application Priority Data
Mar. 25, 2025 (KR) 10-2025-0038313

(51) Int. Cl. G02B 6/42; H10B 80/00; H10D 89/10; H10W 20/20; H10W 74/10; H10W 90/00; H10W 90/10; H10W 90/20

(52) U.S. Cl. CPC G02B 6/4249; G02B 6/4204; G02B 6/4243; G02B 6/4261; G02B 6/428; H10B 80/00; H10D 89/10; H10W 20/213; H10W 74/117; H10W 90/10; H10W 90/297; H10W 90/734

(57) ABSTRACT

A processor package includes an interposer, a memory on the interposer, a processor on the interposer, and an optical engine on the interposer, where the optical engine includes a photonic integrated circuit (PIC) chip including circuit elements configured for photoelectric conversion, and a coupling structure on the PIC chip and configured to provide a light input/output path, and the coupling structure includes, on an upper portion thereof, at least one groove structure configured for alignment with a fiber array unit (FAU).

### CROSS-REFERENCE TO RELATED APPLICATION

This application is based on and claims priority to Korean Patent Application No. 10-2025-0038313, filed on Mar. 25, 2025, in the Korean Intellectual Property Office, the disclosure of which is incorporated by reference herein in its entirety.

### BACKGROUND

### 1. Field

The disclosure relates to a processor package, an electronic device including the processor package, and a method of manufacturing the processor package.

### 2. Description of Related Art

Silicon photonics co-packaged optics (CPO) are being considered as a way to implement ultra-high bandwidth and low-power consumption interconnection required in artificial intelligence (AI) systems.

To integrate the CPO with a host integrated circuit (IC) such as a graphics processing unit (GPU), a central processing unit (CPU), and a field-programmable gate array (FPGA), a substrate packaging scheme is mainly used. This scheme transmits a signal serialized in the host IC to an optical engine through an organic substrate.

In one example of related art, the input/output (I/O) density of the organic substrate is about 100 mm², and the transmission loss is about 0.2 dB/mm/GHz. A minimum interval between chips is about 1.5 mm, and signals of ~20 GHz are transmitted. This corresponds to a loss of about 6 dB. In a related art substrate packaging scheme, the CPO is implemented through −6 dB channel packaging for transmission from the host IC to the optical engine. This scheme receives an input in the form of a serialized signal, such that channel loss increases in proportion to frequency as interconnection speeds increase. As a result, a scheme for efficient signal transmission between the host IC and the optical engine is being explored.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided are a processor package integrated with an optical engine, an electronic device including the processor package, and a method of manufacturing the processor package.

Additional aspects will be set forth in part in the description which follows and, in part, will be apparent from the description, or may be learned by practice of the presented embodiments of the disclosure.

According to an aspect of the disclosure, a processor package may include an interposer, a memory on the interposer, a processor on the interposer, and an optical engine on the interposer, where the optical engine may include a photonic integrated circuit (PIC) chip comprising circuit elements configured for photoelectric conversion, and a coupling structure on the PIC chip and configured to provide a light input/output path, and the coupling structure may include, on an upper portion thereof, at least one groove structure configured for alignment with a fiber array unit (FAU).

The optical engine may include an electronic integrated circuit (EIC) chip on the PIC chip and configured to drive the circuit elements of the PIC chip.

The at least one groove structure may be configured for alignment with a protrusion portion of the FAU.

The processor package may include a stiffener around the memory, the processor, and the optical engine, the stiffener including a guide structure configured for attachment and detachment of the FAU, where the stiffener includes a clamp configured to fix the FAU, and the clamp is on opposite ends of the guide structure.

The processor package a holder configured to fix the FAU.

The processor package may include a substrate on which the interposer is provided and a holder configured to fix the FAU, where the holder is configured to pivot around a hinge on the substrate.

The processor package may include a stiffener around the memory, the processor, and the optical engine, the stiffener including a guide structure configured for attachment and detachment of the FAU, and a holder configured to fix the FAU, and where the holder is configured to pivot around a hinge on the stiffener.

The coupling structure may include a light-transmissive block comprising at least one micro-lens therein, and a receptacle including the at least one groove structure and on the light-transmissive block.

The coupling structure may include a light-transmissive block including at least one micro-lens on at least one of an upper portion and a lower portion thereof.

The at least one micro-lens may include a first micro-lens having negative refractive power and a second micro-lens having positive refractive power, the coupling structure may include a first light-transmissive block and a second light-transmissive block on the first light-transmissive block, the first micro-lens is on an upper portion of the first light-transmissive block, and the second micro-lens is on a lower portion of the second light-transmissive block.

According to an aspect of the disclosure, an electronic device may include a processor package, an FAU, and an output interface connected to the processor package. The processor package may include an interposer, a memory on the interposer, a processor on the interposer, and an optical engine on the interposer, where the optical engine includes a PIC chip including circuit element configured for photoelectric conversion, and a coupling structure on the PIC chip and configured to provide a light input/output path, and where the coupling structure comprises, on an upper portion thereof, at least one groove structure that aligns with the FAU.

The optical engine may include an EIC chip on the PIC chip and configured to drive the circuit elements of the PIC chip.

The FAU may include a protrusion portion corresponding to the at least one groove structure of the coupling structure.

The electronic device may include a stiffener around the memory, the processor, and the optical engine, the stiffener including a guide structure to and from which the FAU is attached and detached, where the stiffener includes a clamp fixing the FAU, and wherein the clamp is on opposite ends of the guide structure.

The electronic device may include a holder fixing the FAU.

The electronic device may include a substrate on which the interposer is provided and a holder fixing the FAU, where the holder is configured to pivot around a hinge provided on the substrate.

The electronic device may include a stiffener around the memory, the processor, and the optical engine, the stiffener including a guide structure to and from which the FAU is attached and detached and a holder fixing the FAU, where the holder is configured to pivot around a hinge on the stiffener.

According to an aspect of the disclosure, a method of manufacturing a processor package may include providing a coupling structure including at least one groove structure, forming an optical engine by arranging, on a PIC chip, the coupling structure and an EIC chip, the PIC chip including circuit elements configured for photoelectric conversion and the EIC chip being configured to drive the circuit elements, depositing a protective film on the coupling structure, applying a mold material to regions of the coupling structure, the EIC chip, and the coupling structure, exposing the at least one groove structure by removing the protective film, and providing the optical engine on an interposer.

The method may include providing a stiffener on the EIC chip, the stiffener including a guide structure configured for attachment and detachment of a FAU.

The coupling structure may include at least one micro-lens, the at least one micro-lens may include a first micro-lens having negative refractive power and a second micro-lens having positive refractive power, the coupling structure may include a first light-transmissive block and a second light-transmissive block provided on the first light-transmissive block, where the first micro-lens is on upper portion of the first light-transmissive block, and the second micro-lens is on a lower portion of the second light-transmissive block.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a plan view illustrating a configuration of a processor package according to an embodiment;

FIG. 2 is a cross-sectional view illustrating a configuration of a processor package according to an embodiment;

FIG. 3 is a cross-sectional view illustrating a configuration of a processor package according to an embodiment;

FIG. 4 is a cross-sectional view illustrating a configuration of a processor package according to an embodiment;

FIGS. 5 and 6 are diagrams illustrating a method of manufacturing a processor package according to an embodiment;

FIGS. 7 and 8 are cross-sectional views illustrating configurations of a coupling structure according to an embodiment;

FIGS. 9, 10 and 11 are cross-sectional views illustrating a configuration of a detachable structure of a stiffener and a fiber array unit (FAU), according to an embodiment; and

FIG. 12 is a block diagram illustrating a configuration of an electronic apparatus according to an embodiment.

### DETAILED DESCRIPTION

Reference will now be made in detail to embodiments, examples of which are illustrated in the accompanying drawings, wherein like reference numerals refer to like elements throughout. In this regard, the current embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments will be described in detail with reference to the accompanying drawings. Embodiments to be described are merely examples, and various modifications may be made from such embodiments. In the drawings, like reference numerals denote like components, and sizes of components in the drawings may be exaggerated for convenience of explanation.

In the following description, when a component is referred to as being “above” or “on” another component, it may be directly on an upper, lower, left, or right side of the other component while making contact with the other component or may be above an upper, lower, left, or right side of the other component without making contact with the other component.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In addition, terms such as “unit” and “module” described in the specification may indicate a unit that processes at least one function or operation, and this may be implemented as hardware or software, or may be implemented as a combination of hardware and software.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

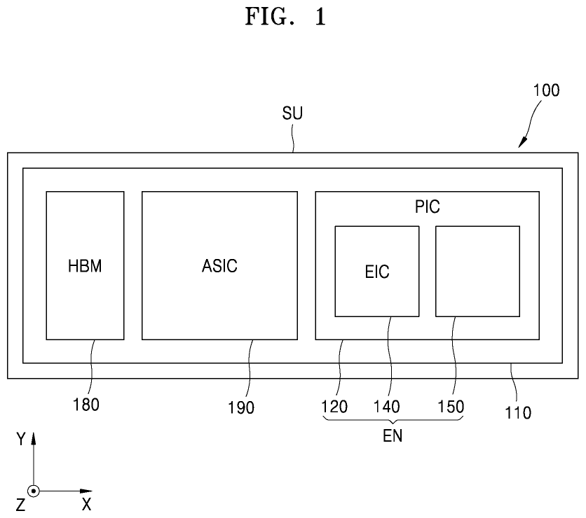

FIG. 1 is a plan view illustrating a configuration of a processor package according to an embodiment.

A processor package 100 according to an embodiment may have a structure in which an optical engine EN is packaged together with a host integrated circuit (IC).

The processor package 100 may include an interposer 110, a memory 180 arranged on the interposer 110, a processor (or an application-specific integrated circuit (ASIC)) 190, and the optical engine EN. The interposer 110 may be arranged on a substrate SU. The substrate SU may be a package substrate, such as a printed circuit board (PCB).

The interposer 110 may be a microcircuit board used to integrate semiconductor chips manufactured in different processes, such as a memory element and a logic element as a single package. A wire pitch difference between the IC chip and the PCB may be buffered by the interposer 110. A wire pitch of a circuit included in the interposer 110 may be between the IC chip and the PCB. The interposer 110 may be a silicon interposer or a redistribution layer (RDL) interposer.

The memory 180 may be, but is not limited to, a high-bandwidth memory (HBM) 180.

The processor 190 may be a graphical processing unit (GPU) or may include a central processing unit (CPU) or a field programmable gate array (FPGA).

The optical engine EN may include circuit elements for photoelectric conversion. The optical engine EN may convert an electrical signal into an optical signal or an optical signal into an electrical signal at an end of an optical interconnection, and may also provide a transmission path of light input and output through optical communication.

The optical engine EN may include a photonic IC (PIC) chip 120 including circuit elements for photoelectric conversion and a coupling structure 150 arranged on the PIC chip 120 to provide a light input/output path. The optical engine EN may further include an electronic IC (EIC) chip 140 arranged on the PIC chip 120 to drive photoelectric conversion circuit elements.

The optical engine EN may receive an optical signal and convert the optical signal into an electrical signal for transmission to the processor 190 or convert an electrical signal from the processor 190 into an optical signal for transmission to an outside. In the processor package 100, such signal transmission between the optical engine EN and the processor 190 may be performed by the interposer 110, thereby minimizing a transmission loss. Furthermore, a transmission loss may be significantly more reduced when the optical engine EN is directly arranged on the interposer 110 rather than being connected to the host IC through a PCB.

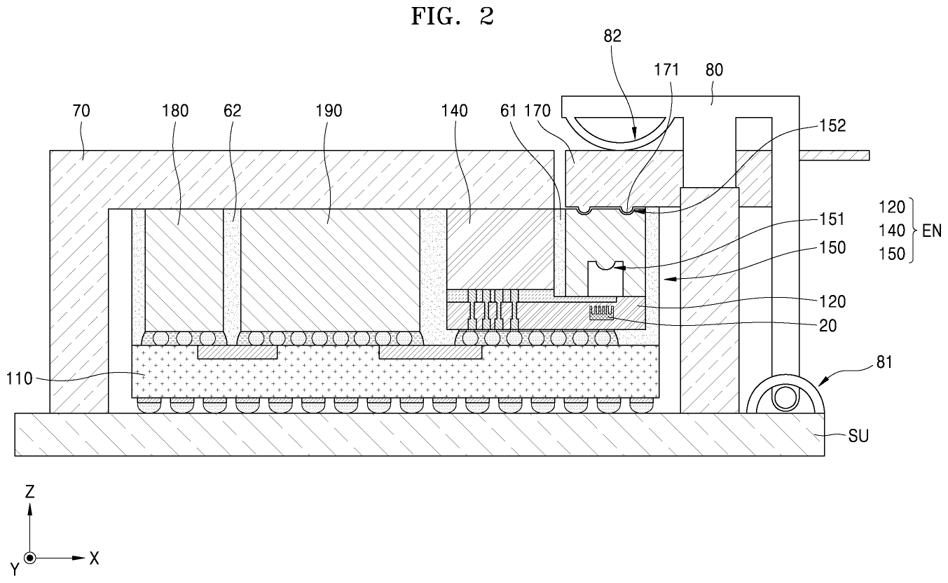

FIG. 2 is a cross-sectional view illustrating a configuration of a processor package according to an embodiment.

The processor package 100 may include the interposer 110, the memory 180, the processor 190, and the optical engine EN. The optical engine EN may include the PIC chip 120, the EIC chip 140, and the coupling structure 150.

The memory 180, the processor 190, and the optical engine EN may be electrically connected by the interposer 110. In the interposer 110, a silicon through electrode or a redistribution layer (RDL). The interposer 110 may be a silicon interposer or an RDL interposer.

The PIC chip 120 may include a photoelectric conversion element, an optical waveguide, an electrical wire, an optical coupler, etc. A coupling element 20 may be arranged at an end of the PIC chip 120. The coupling element 20 may be arranged at a position facing a lens 151 to change a path of light traveling in the PIC chip 120 into a direction (a Z direction) toward the lens 151. The coupling element 20 may also change a path of light incident through the lens 151 to cause the light to travel in the PIC chip 120. The coupling element 20 may be referred to as a vertical emitter. The coupling element 20 may be, for example, a grating coupler. Various circuit elements included in the PIC chip 120 are not shown, and a shown structure is a conceptual example and is not limited to a shown form.

A region between the EIC chip 140 and the coupling structure 150 may be filled with a mold material 61, and regions among the memory 180, the processor 190, and the optical engine EN may also be filled with a mold material 62. However, the disclosure is not limited thereto.

The coupling structure 150 may include at least one lens 151. The lens 151 may be a micro-lens or a meta-lens including a nano structure. The coupling structure 150 may include at least one groove structure 152 for precise alignment with a fiber array unit (FAU) 170. That is, the FAU 170 may be positioned on the coupling structure 150, and the FAU 170 may be aligned with the coupling structure 150 by use of the groove 152 and a protrusion portion 171 of the FAU 170. In some embodiments, the lens 151 may be provided on a lower portion of the coupling structure 150, the at least one groove structure 152 may be provided in an upper portion of the coupling structure 150. However, the disclosure is not limited thereto.

The coupling structure 150 may include a glass material or a transparent plastic material. The coupling structure 150 may include a light-transmissive block. The at least one lens 151 may be provided on at least one of an upper portion and a lower portion of the light-transmissive block. The FAU 170 may be provided on the coupling structure 150.

The FAU 170 may be arranged facing the lens 151 to enable input and output of light between the PIC chips 120 through the lens 151. The FAU 170 may include a protrusion portion 171 corresponding to the at least one groove structure 152 of the coupling structure 150. The FAU 170 may be arranged to be placed on the coupling structure 150 through the at least one groove structure 152 of the coupling structure 150, and may be precisely aligned with the coupling structure 150 through the at least one groove structure 152 by way of the protrusion portion 171.

A holder 80 may be provided on the FAU 170 to fix the FAU 170. The holder 80 may include a hinge 81 such that the holder 80 may pivot around the hinge 81. The hinge 81 may be provided on, for example, the substrate SU. The holder 80 may include a spring 82 to closely contact and fix the FAU 170 and the coupling structure 150 with each other.

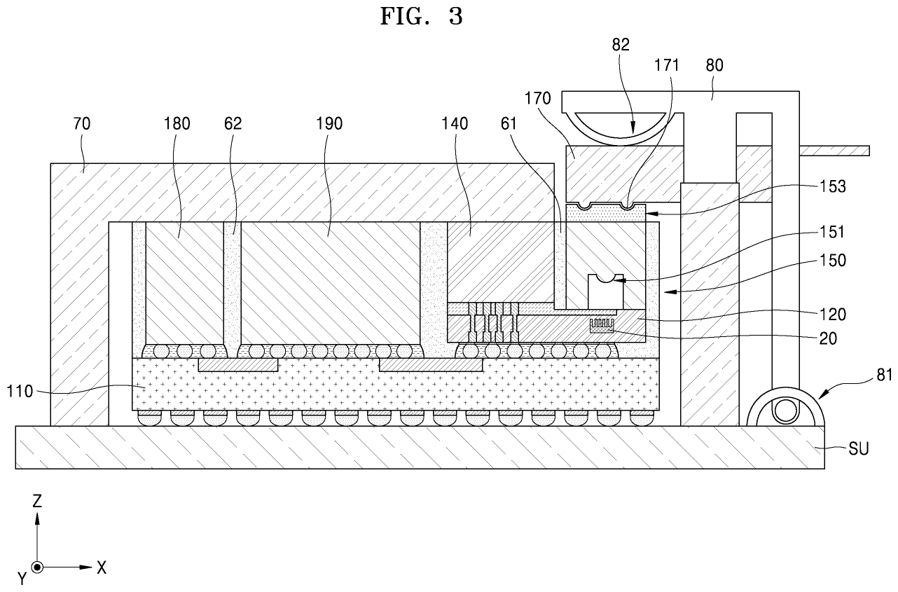

FIG. 3 is a cross-sectional view illustrating a configuration of a processor package according to an embodiment. Description of aspects that are the same as or similar to those described above may be omitted.

Referring to FIG. 3, the coupling structure 150 may include a receptacle 153 for precise alignment with the FAU 170. The receptacle 153 may be provided on the light-transmissive block of the coupling structure 150. The receptacle 153 may include at least one groove structure for precise alignment with the FAU 170.

The FAU 170 may include a protrusion portion 171 corresponding to the at least one groove structure of the receptacle 153 of the coupling structure 150. The FAU 170 may be arranged to be placed on the receptacle 153 of the coupling structure 150 through the at least one groove structure of the receptacle 153 and may be precisely aligned with the coupling structure 150 by way of the protrusion portion 171.

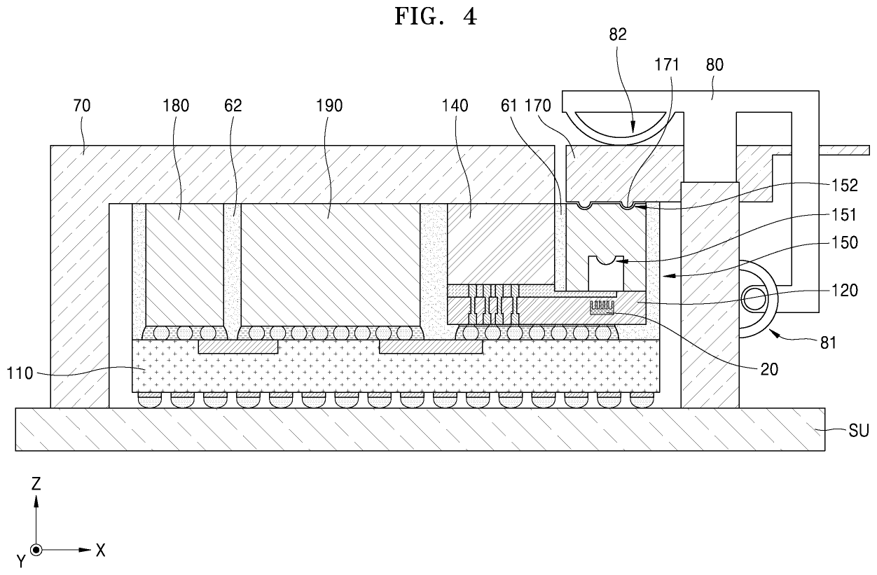

FIG. 4 is a cross-sectional view illustrating a configuration of a processor package according to an embodiment. Description of aspects that are the same as or similar to those described above may be omitted.

While the hinge 81 is provided on the substrate SU in FIG. 2 as an example, the hinge 81 may also be provided on an outer wall of a stiffener 70 as shown in FIG. 4.

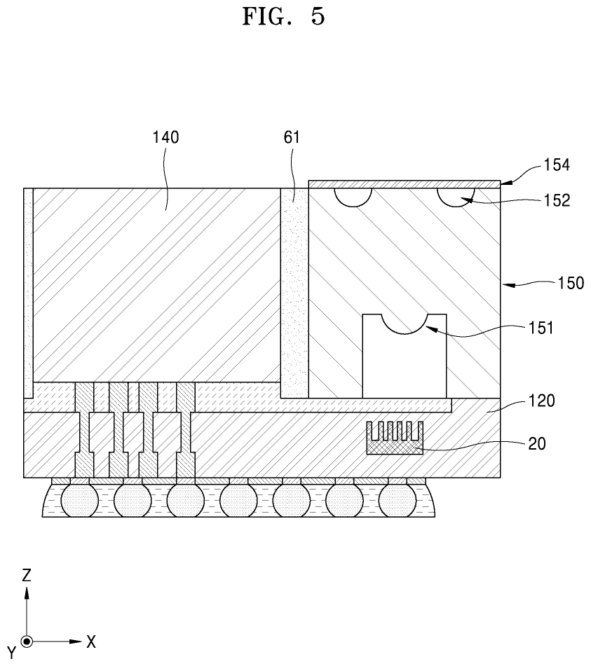

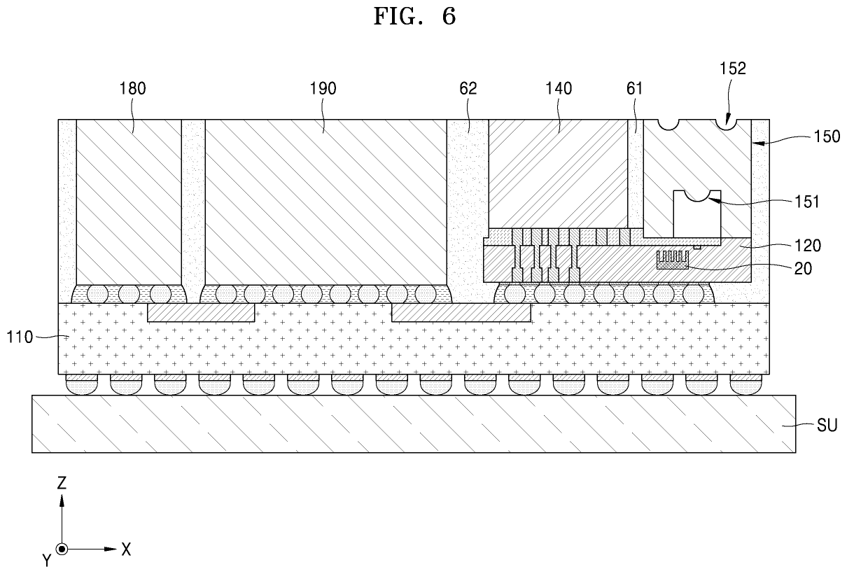

FIGS. 5 and 6 are diagrams illustrating a method of manufacturing a processor package according to an embodiment.

Referring to FIG. 5, a protective film 154 may be deposited on the at least one groove structure 152 of the coupling structure 150, and the EIC chip 140 and the coupling structure 150 may be bonded to the PIC chip 120. Referring to FIG. 6, the memory 180, the processor 190, and the optical engine EN may be arranged on the interposer 110. After the regions among the memory 180, the processor 190, and the optical engine EN are filled with the mold materials 61 and 62, the at least one groove structure 152 of the coupling structure 150 may be exposed by grinding a surface to remove the protective film 154, and polishing may be performed.

A photoresist may be applied onto the optical engine EN and then dicing may be performed on the optical engine EN. Thereafter, the regions among the memory 180, the processor 190, and the optical engine EN may be filled with the mold materials 61 and 62 and then grinded, thereby removing the photoresist. Alternatively, the at least one groove structure 152 may be filled with carbon, the regions among the memory 180, the processor 190, and the optical engine EN may be filled with the mold materials 61 and 62 and grinded, and then the carbon may be removed through ashing.

The interposer 110 in which the memory 180, the processor 190, and the optical engine EN are integrated together may be arranged on the substrate SU, and a stiffener including a guide structure to and from which the FAU 170 is attached and detached may be included.

The FAU 170 may be arranged on the coupling structure 150 having the at least one groove structure 152 manufactured in this way, or the receptacle 153 of FIG. 3 may be further provided on the coupling structure 150 such that the FAU 170 may be arranged on the receptacle 153.

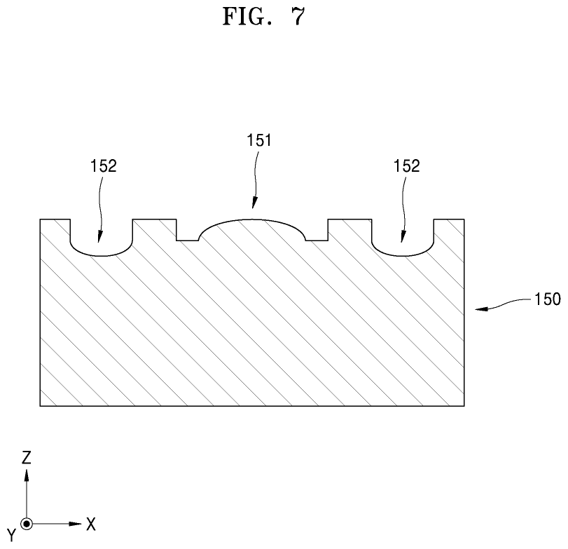

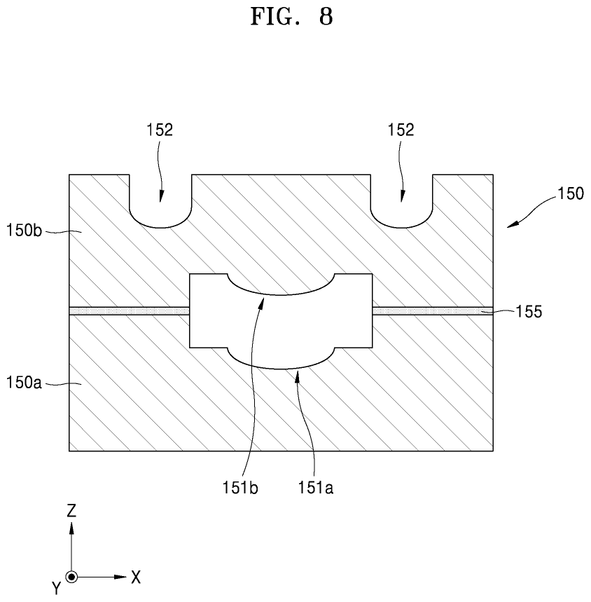

FIGS. 7 and 8 are cross-sectional views illustrating configurations of a coupling structure according to embodiments. Description of aspects that are the same as or similar to those described above may be omitted.

Referring to FIG. 7, the lens 151 may be provided, together with the at least one groove structure 152, on an upper portion of a light-transmissive block of the coupling structure 150.

Alternatively, referring to FIG. 8, the coupling structure 150 may include a first light-transmissive block 150a and a second light-transmissive block 150b. The second light-transmissive block 150b may be provided on the first light-transmissive block 150a. The first light-transmissive block 150a and the second light-transmissive block 150b may be coupled through bonding via an adhesive layer 155. The first light-transmissive block 150a and the second light-transmissive block 150b may respectively include lenses 151a and 151b. The first lens 151a and the second lens 151b may include glass or silicon.

The first lens 151a and the second lens 151b may be provided to face each other. In some embodiments, the first lens 151a may be provided on an upper portion of the first light-transmissive block 150a, and the second lens 151b may be provided on a lower portion of the second light-transmissive block 150b to face the first lens 151a. A space between the first lens 151a and the second lens 151b may be filled with air or epoxy. In some embodiments, the first lens 151a may be a concave lens having negative refractive power, and may amplify a diffusion angle of a beam emitted from the coupling element 20. In some embodiments, the second lens 151b may be a convex lens having positive refractive power, and may form parallel light by reducing the diffusion angle of the beam having the diffusion angle amplified through the first lens 151a and expand a size of the beam to fit for the FAU 170 of FIG. 2.

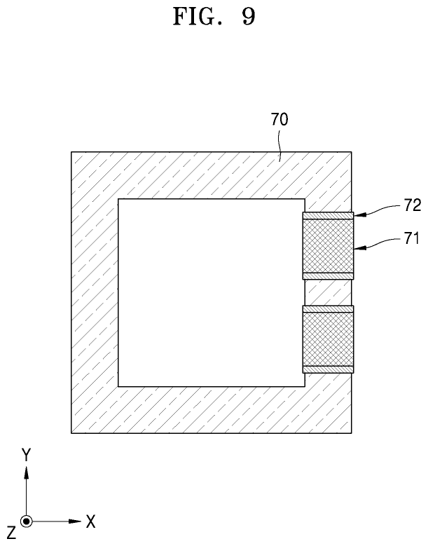

FIGS. 9, 10 and 11 are cross-sectional views illustrating a schematic configuration of a detachable structure of a stiffener and an FAU according to an embodiment.

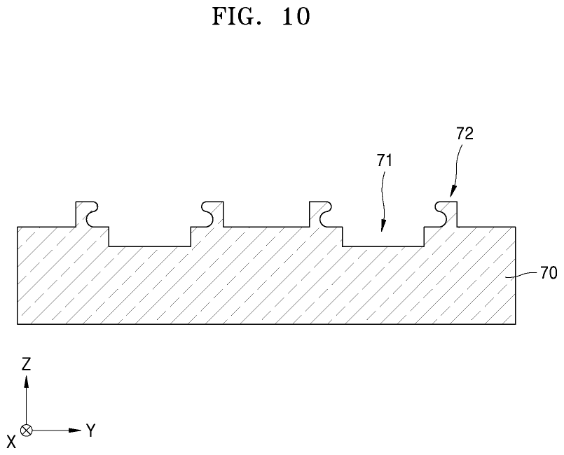

Referring to FIGS. 9 and 10, the stiffener 70 provided on a circumference of the memory 180, the processor 190, and the optical engine EN may include a guide structure 71 for coupling with the FAU 170. The guide structure 71 may include a trench structure formed at a level lower than an upper surface of the stiffener 70, and the FAU 170 may be attached and detached through the guide structure 71 of the stiffener 70. The stiffener 70 may include a clamp 72 for fixing the FAU 170. The clamp 72 may be provided on opposite ends of the guide structure 71 and may include a groove structure for fixing the holder 80.

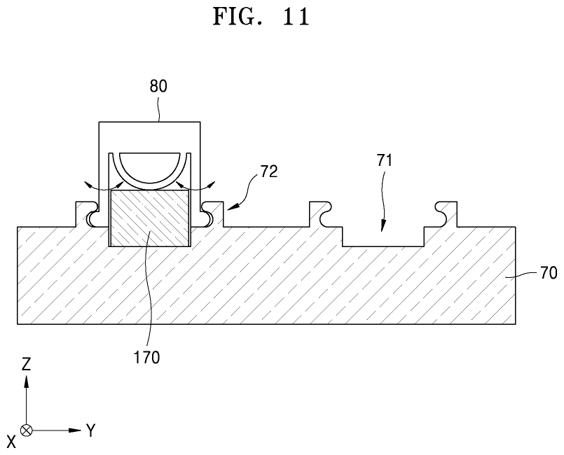

Referring to FIG. 11, the FAU 170 may be inserted and adhered through the guide structure 71 of the stiffener 70 to be aligned with the coupling structure 150, and may be fixed by the clamp 72 of the stiffener 70 and the holder 80. The holder 80 may be detached from the clamp 72 by a physical force, and thus the FAU 170 may also be detached.

According to embodiments, in 2.5D co-packaged optics (CPO), the processor package 100 in which the FAU 170 may be attached and detached may be implemented, and the coupling structure 150 and the FAU 170 may be precisely aligned by not only active alignment of the lens 151 of the coupling structure 150 and the FAU 170, but also passive alignment of the guide structure 71 and the clamp 72 of the stiffener 70 and the holder 80, thereby reducing a data transmission loss.

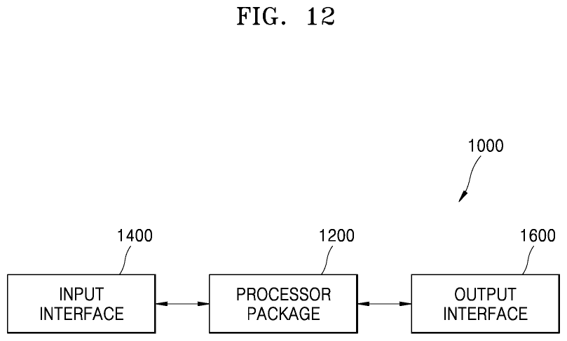

FIG. 12 is a block diagram of a configuration of an electronic apparatus according to an embodiment.

An electronic device 1000 may include a processor package 1200, an input interface 1400, and an output interface 1600. The input interface 1400 and the output interface 1600 may be electrically connected to the processor package 1200. The processor package 1200 may include the above-described processor package 100 or a processor package having a modified or combined structure.

The above-described embodiments may be summarized as below.

A processor package according to an embodiment may include an interposer, a memory provided on the interposer, a processor provided on the interposer, and an optical engine provided on the interposer, in which the optical engine includes a PIC chip including circuit elements for photoelectric conversion and a coupling structure provided on the PIC chip to provide a light input/output path, and the coupling structure includes, on an upper portion thereof, at least one groove structure for precise alignment with an FAU.

The optical engine may further include an EIC chip arranged on the PIC chip to drive the circuit elements.

The FAU may include a protrusion portion corresponding to the at least one groove structure of the coupling structure.

The processor package may further include a stiffener arranged around the memory, the processor, and the optical engine and including a guide structure to and from which the FAU is attached and detached, in which the stiffener includes a clamp provided to fix the FAU, and the clamp is provided on opposite ends of the guide structure.

The processor package may further include a holder fixing the FAU.

The processor package may further include a substrate on which the interposer is provided and a holder fixing the FAU, in which the holder pivots around a hinge provided on the substrate.

The processor package may further include a holder fixing the FAU, in which the holder pivots around a hinge provided on the substrate.

The coupling structure may include a light-transmissive block having at least one micro-lens formed therein and a receptacle including the at least one groove structure and provided on the light-transmissive block.

The coupling structure may include a light-transmissive block having at least one micro-lens formed on at least one of an upper portion and a lower portion thereof.

The at least one micro-lens may include a first micro-lens having negative refractive power and a second micro-lens having positive refractive power, the coupling structure may include a first light-transmissive block and a second light-transmissive block provided on the first light-transmissive block, the first micro-lens may be provided on an upper portion of the first light-transmissive block, and the second micro-lens may be provided on a lower portion of the second light-transmissive block.

An electronic device according to an embodiment includes a processor package and an output interface electrically connected to the processor package, in which the processor package includes an interposer, a memory provided on the interposer, a processor provided on the interposer, and an optical engine provided on the interposer, and the optical engine includes a PIC chip including circuit elements for photoelectric conversion and a coupling structure provided on the PIC chip to provide a light input/output path, and the coupling structure includes, on an upper portion thereof, at least one groove structure for precise alignment with an FAU.

The optical engine may further include an EIC chip arranged on the PIC chip to drive the circuit elements.

The FAU may include a protrusion portion corresponding to the at least one groove structure of the coupling structure.

The electronic device may further include a stiffener arranged around the memory, the processor, and the optical engine and including a guide structure to and from which the FAU is attached and detached, in which the stiffener includes a clamp provided to fix the FAU, and the clamp is provided on opposite ends of the guide structure.

The electronic device may further include a holder fixing the FAU.

The electronic device may further include a substrate on which the interposer is provided and a holder fixing the FAU, in which the holder pivots around a hinge provided on the substrate.

The electronic device may further include a stiffener arranged around the memory, the processor, and the optical engine and including a guide structure to and from which the FAU is attached and detached, and a holder fixing the FAU, in which the holder pivots around a hinge provided on the stiffener.

A method of manufacturing a processor package according to an embodiment includes providing a coupling structure including at least one groove structure, arranging, on a PIC chip including circuit elements for photoelectric conversion, the coupling structure and an EIC chip configured to drive the circuit elements, to form an optical engine, depositing a protective film on the coupling structure, applying a mold material to regions among the coupling structure, the EIC chip, and the coupling structure, removing the protective film to expose the at least one groove structure, and arranging the optical engine on an interposer.

The method may further include a stiffener including a guide structure to and from which an FAU is attached and detached, in which the coupling structure includes at least one micro-lens and at least one groove structure for precise alignment with the FAU.

The at least one micro-lens may include a first micro-lens having negative refractive power and a second micro-lens having positive refractive power, the coupling structure may include a first light-transmissive block and a second light-transmissive block provided on the first light-transmissive block, the first micro-lens may be provided on an upper portion of the first light-transmissive block, and the second micro-lens may be provided on a lower portion of the second light-transmissive block.

While the above-described processor package, electronic device including the processor package, and method of manufacturing the processor package have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included.

In the above-described processor package and electronic device including the processor package, the optical engine may be packaged together with the processor, etc., on the interposer, thereby reducing a data transmission loss.

According to the above-described method of manufacturing the processor package, the processor package having a small data transmission loss may be manufactured with good yields.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A processor package comprising:
an interposer;
a memory on the interposer;
a processor on the interposer; and
an optical engine on the interposer,
wherein the optical engine comprises:
a photonic integrated circuit (PIC) chip comprising circuit elements configured for photoelectric conversion; and
a coupling structure on the PIC chip and configured to provide a light input/output path, and
wherein the coupling structure comprises, on an upper portion thereof, at least one groove structure configured for alignment with a fiber array unit (FAU).

2. The processor package of claim 1, wherein the optical engine further comprises an electronic integrated circuit (EIC) chip on the PIC chip and configured to drive the circuit elements of the PIC chip.

3. The processor package of claim 1, wherein the at least one groove structure is configured for alignment with a protrusion portion of the FAU.

4. The processor package of claim 1, further comprising a stiffener around the memory, the processor, and the optical engine, the stiffener comprising a guide structure configured for attachment and detachment of the FAU,
wherein the stiffener comprises a clamp configured to fix the FAU, and
wherein the clamp is on opposite ends of the guide structure.

5. The processor package of claim 1, further comprising a holder configured to fix the FAU.

6. The processor package of claim 1, further comprising:
a substrate on which the interposer is provided; and
a holder configured to fix the FAU,
wherein the holder is configured to pivot around a hinge on the substrate.

7. The processor package of claim 1, further comprising:
a stiffener around the memory, the processor, and the optical engine, the stiffener comprising a guide structure configured for attachment and detachment of the FAU; and
a holder configured to fix the FAU,
wherein the holder is configured to pivot around a hinge on the stiffener.

8. The processor package of claim 1, wherein the coupling structure comprises:
a light-transmissive block comprising at least one micro-lens therein; and
a receptacle comprising the at least one groove structure and on the light-transmissive block.

9. The processor package of claim 1, wherein the coupling structure comprises a light-transmissive block comprising at least one micro-lens on at least one of an upper portion and a lower portion thereof.

10. The processor package of claim 9, wherein the at least one micro-lens comprises a first micro-lens having negative refractive power and a second micro-lens having positive refractive power,
wherein the coupling structure comprises a first light-transmissive block and a second light-transmissive block on the first light-transmissive block,
wherein the first micro-lens is on an upper portion of the first light-transmissive block, and
wherein the second micro-lens is on a lower portion of the second light-transmissive block.

11. An electronic device comprising:
a processor package;
a fiber array unit (FAU); and
an output interface connected to the processor package,
wherein the processor package comprises:
an interposer;
a memory on the interposer;
a processor on the interposer; and
an optical engine on the interposer, and
wherein the optical engine comprises:
a photonic integrated circuit (PIC) chip comprising circuit elements configured for photoelectric conversion; and
a coupling structure on the PIC chip and configured to provide a light input/output path, and
wherein the coupling structure comprises, on an upper portion thereof, at least one groove structure that aligns with the FAU.

12. The electronic device of claim 11, wherein the optical engine further comprises an electronic integrated circuit (EIC) chip on the PIC chip and configured to drive the circuit elements of the PIC chip.

13. The electronic device of claim 11, wherein the FAU comprises a protrusion portion corresponding to the at least one groove structure of the coupling structure.

14. The electronic device of claim 11, further comprising a stiffener around the memory, the processor, and the optical engine, the stiffener comprising a guide structure to and from which the FAU is attached and detached,
wherein the stiffener comprises a clamp fixing the FAU, and
wherein the clamp is on opposite ends of the guide structure.

15. The electronic device of claim 11, further comprising a holder fixing the FAU.

16. The electronic device of claim 11, further comprising:
a substrate on which the interposer is provided; and
a holder fixing the FAU,
wherein the holder is configured to pivot around a hinge provided on the substrate.

17. The electronic device of claim 11, further comprising:
a stiffener around the memory, the processor, and the optical engine, the stiffener comprising a guide structure to and from which the FAU is attached and detached; and
a holder fixing the FAU,
wherein the holder is configured to pivot around a hinge on the stiffener.

18. A method of manufacturing a processor package, the method comprising:
providing a coupling structure comprising at least one groove structure;
forming an optical engine by arranging, on a photonic integrated circuit (PIC) chip, the coupling structure and an electronic integrated circuit (EIC) chip, the PIC chip comprising circuit elements configured for photoelectric conversion and the EIC chip being configured to drive the circuit elements;
depositing a protective film on the coupling structure;
applying a mold material to regions of the coupling structure, the EIC chip, and the coupling structure;
exposing the at least one groove structure by removing the protective film; and
providing the optical engine on an interposer.

19. The method of claim 18, further comprising providing a stiffener on the EIC chip, the stiffener comprising a guide structure configured for attachment and detachment of a fiber array unit (FAU).

20. The method of claim 18, wherein the coupling structure comprises at least one micro-lens,
wherein the at least one micro-lens comprises a first micro-lens having negative refractive power and a second micro-lens having positive refractive power,
wherein the coupling structure further comprises a first light-transmissive block and a second light-transmissive block provided on the first light-transmissive block,
wherein the first micro-lens is on upper portion of the first light-transmissive block, and
wherein the second micro-lens is on a lower portion of the second light-transmissive block.
